(19) United States
(12) Patent Application Publication
(10) Pub. No.: US 2025/0355039 A1
(43) Pub. Date: Nov. 20, 2025

(54) PANEL INSPECTION DEVICE

(71) Applicant: Century Technology (ShenZhen) Corp., LTD., Shen-zhen (CN)

(72) Inventors: Tzu-Hsiu LIU, Shen-zhen (CN); Jiang-Lin LIU, Shen-zhen (CN)

(21) Appl. No.: 19/207,565

(22) Filed: May 14, 2025

(30) Foreign Application Priority Data
May 15, 2024 (CN) 202410602440.8

(51) Int. Cl. G01R 31/28

(52) U.S. Cl. CPC G01R 31/2844

(57) ABSTRACT

A panel inspection device comprises an inspection plate, a carrier plate, a backlight module, a bracket assembly, and a first probe assembly. The inspection plate has a first edge and a second edge. The carrier plate is disposed on the inspection plate, forming an opening with the first edge and the second edge. The backlight module corresponds to the opening. The bracket assembly comprises a first bracket, which is disposed on the first edge and includes a first sliding groove. The first probe assembly includes a plurality of first probes. The first probe assembly is slidably disposed in the first sliding groove and is movable between a first position and a second position. When the first probe assembly is in the second position, the first probes correspond to the inner side of the first edge.

### CROSS-REFERENCE TO RELATED APPLICATION

This application claims priority to Chinese Patent Application No. CN 202410602440.8 filed on May 15, 2024, the disclosures of which are incorporated herein in their entirety by reference.

### TECHNICAL FIELD

The present invention relates to a panel inspection device, and more particularly refers to a panel inspection device capable of adjusting probe positions and sharing a backlight module.

### BACKGROUND

Prior to packaging, a liquid crystal display (LCD) panel must undergo inspection operations (e.g., light-up tests) by inputting power and control signals to drive the LCD panel, allowing observation of whether the display state of the LCD panel meets the required standards. To inspect large quantities of LCD panels, the LCD panels will be subjected to inspection operations by means of an inspection fixture. However, the contact positions of LCD panels with different specifications (sizes) may not be identical. Therefore, the inspection fixture must be designed with probe specifications and positions for matching LCD panels with different specifications in order to drive them properly. Additionally, the backlight module of the inspection fixture cannot be shared among LCD panels with different specifications, necessitating the construction of different inspection fixtures according to the LCD panel specifications.

### SUMMARY

In view of the above, the present invention, according to some embodiments, provides a panel inspection device comprising an inspection plate, a carrier plate, a backlight module, a bracket assembly, and a first probe assembly. The inspection plate has a first edge and a second edge. The carrier plate is disposed on the inspection plate, forming an opening with the first edge and the second edge. The backlight module corresponds to the opening. The bracket assembly comprises a first bracket, which is disposed on the first edge and includes a first sliding groove. The first probe assembly includes a plurality of first probes. The first probe assembly is slidably disposed in the first sliding groove and is movable between a first position and a second position. When the first probe assembly is in the second position, the first probes correspond to the inner side of the first edge.

According to some embodiments, the panel inspection device further comprises a detection housing and an actuating assembly. The detection housing is connected to the inspection plate. The actuating assembly connects the detection housing and the bracket assembly, wherein when actuated, the first probe is positioned on the inner side of the first edge.

According to some embodiments, the actuating assembly comprises a first elastic component, a linkage assembly, and an operating member. The first elastic component is supported between the detection housing and the first bracket and is configured to produce telescopic motion when actuated. The linkage assembly connects the detection housing and the first bracket. The operating member is connected to the linkage assembly, wherein when actuated, the linkage assembly actuates the first elastic component.

According to some embodiments, the first probe assembly further comprises a first probe base. The first probe base has a first adjustment sliding groove and a first adjustment screw. The first adjustment screw is disposed within the first sliding groove and the first adjustment sliding groove. The first sliding groove has a first adjustment direction, and the first adjustment sliding groove has a second adjustment direction, with the first adjustment direction being perpendicular to the second adjustment direction.

According to some embodiments, the first probe assembly further comprises a first connecting plate. The first probes are fixed to the first connecting plate, and the first connecting plate is detachably assembled to the first probe base.

According to some embodiments, the bracket assembly further comprises a second bracket and a second probe assembly. The second bracket is disposed on the second edge and includes a second sliding groove. The second probe assembly comprises a plurality of second probes. The second probe assembly is slidably disposed in the second sliding groove and is movable between a third position and a fourth position. When the second probe assembly is in the fourth position, the second probes correspond to the inner side of the second edge.

According to some embodiments, the actuating assembly further comprises a second elastic component. The second elastic component is supported between the detection housing and the second bracket and is configured to produce telescopic motion when actuated. The linkage assembly connects the detection housing, the first bracket, and the second bracket. The operating member is connected to the linkage assembly, wherein when actuated, the linkage assembly actuates the first elastic component and the second elastic component.

According to some embodiments, the second probe assembly further comprises a second probe base. The second probe base has a second adjustment sliding groove and a second adjustment screw. The second adjustment screw is disposed within the second sliding groove and the second adjustment sliding groove. The second sliding groove has a third adjustment direction, and the second adjustment sliding groove has a fourth adjustment direction, with the third adjustment direction being perpendicular to the fourth adjustment direction.

According to some embodiments, the second probe assembly further comprises a second connecting plate. The second probes are fixed to the second connecting plate, and the second connecting plate is detachably assembled to the second probe base.

According to some embodiments, the panel inspection device further comprises a movable baffle. The movable baffle is slidably disposed on the inspection plate. When actuated, the movable baffle is positioned on the inner side of the first edge. In summary, according to some embodiments of the present invention, a panel inspection device is provided wherein, during inspection, a display panel can be supported on the carrier plate. The first probe assembly, corresponding to the specifications of the display panel, is adjusted to the signal transmission portion of the display panel by sliding in the first sliding groove of the first bracket. When the first probes contact the signal transmission portion, the display mode of the display panel can be controlled to perform the inspection. The carrier plate can support display panels of various sizes, and the inspection light generated by the backlight module is suitable as a backlight source for display panels with different sizes, illuminating the display panel through the opening to inspect the display state of the panel. In some embodiments, when the signal transmission portions of the display panel are located at both the first edge and the second edge, the first probe assembly can be adjusted to the signal transmission portion located at the first edge by sliding in the first sliding groove of the first bracket. The second probe assembly can be adjusted to the signal transmission portion located at the second edge by sliding in the second sliding groove of the second bracket. This allows the panel inspection device to measure and control the display panel using both the first probe assembly and the second probe assembly.

### BRIEF DESCRIPTION OF THE DRAWINGS

The drawings are used for better understanding of the present invention, but not intended to limit the scope of the present invention.

FIG. 1 is a perspective view of a panel inspection device according to some embodiments of the present invention.

FIG. 2 is an exploded view of the panel inspection device according to some embodiments of the present invention.

FIG. 3 is a top view of the panel inspection device according to some embodiments of the present invention.

FIG. 4 is a schematic diagram showing the panel inspection device inspecting a display panel according to some embodiments of the present invention.

FIG. 5A is an enlarged view of area 5A in FIG. 4, showing the first probe corresponding to the first sub-transmission portion.

FIG. 5B is an enlarged view of area 5B in FIG. 4, showing the second probe corresponding to the second sub-transmission portion.

FIG. 6 is a side view of the panel inspection device according to some embodiments of the present invention, showing the position where the linkage assembly has not been actuated.

FIG. 7 is a side view of the panel inspection device according to some embodiments of the present invention, showing the position where the linkage assembly has been actuated.

FIG. 8 is a block diagram of the panel inspection device, the signal generating device, and the signal analyzing device according to some embodiments of the present invention.

Wherein, the numerals and symbols used in the drawings are listed as following.
100: Panel inspection device
101: First surface
102: Inspection plate
103: Second surface
104: Carrier plate
106: Backlight module
108: Bracket assembly
110: First probe assembly
112: First edge
114: Second edge
116: Opening
117: Light-transmitting aperture
118: First bracket
120: First sliding groove
122: First probe
124: Detection housing
126: Actuating assembly
128: First elastic component
130: Linkage assembly
131: First connecting rod
132: Operating member
133: Second connecting rod
134: First probe base
135: Third connecting rod
136: First adjustment sliding groove
138: First adjustment screw
140: First connecting plate
142: Second bracket
144: Second probe assembly
146: Second sliding groove
148: Second probe
150: Second elastic component
152: Second probe base
154: Second adjustment sliding groove
156: Second adjustment screw
158: Second connecting plate
160, 162: Movable baffle
200: Display panel
202: Signal transmission portion
203: Contact
204: First sub-transmission portion
206: Second sub-transmission portion
210: Signal generating device
220: Signal analyzing device
D1: First distance
D2: Second distance
5A, 5B: Area

### DETAILED DESCRIPTION OF DISCLOSED EMBODIMENTS

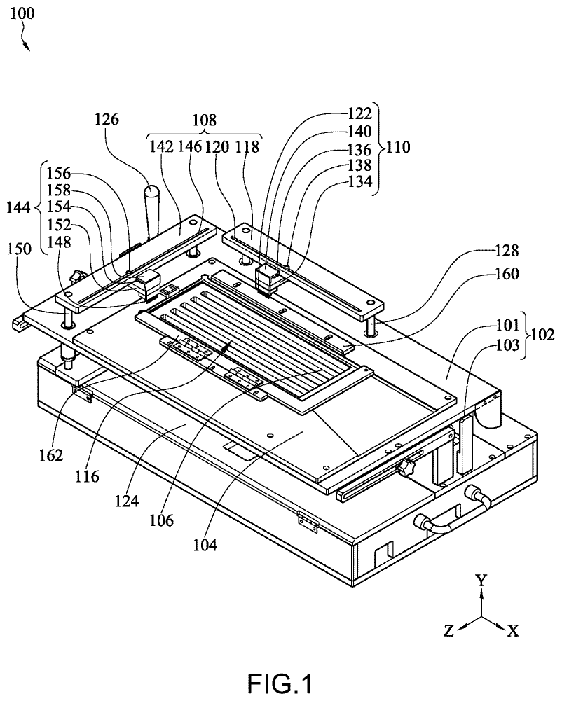

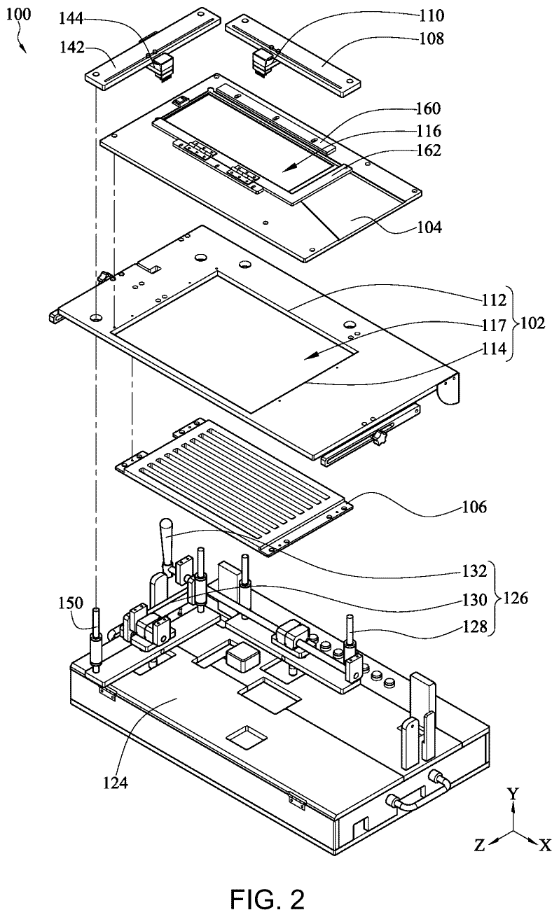

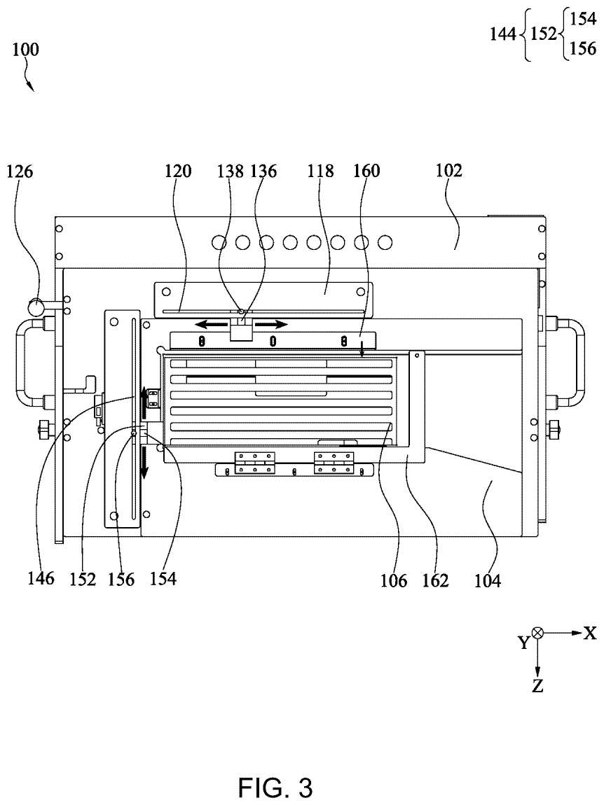

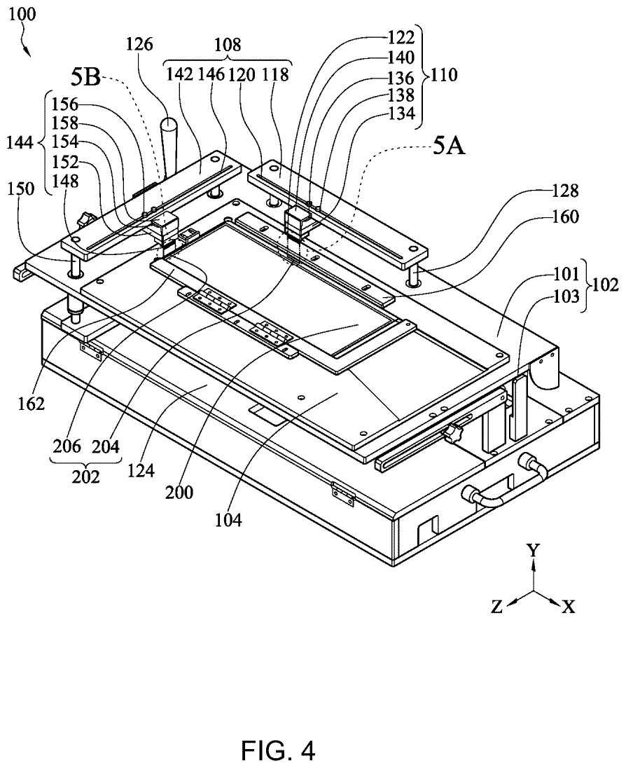

Please refer to FIGS. 1, 2, 3, and 4 together. FIG. 1 is a perspective view of a panel inspection device according to some embodiments of the present invention. FIG. 2 is an exploded view of the panel inspection device according to some embodiments of the present invention. FIG. 3 is a top view of the panel inspection device according to some embodiments of the present invention. FIG. 4 is a schematic diagram showing the panel inspection device inspecting a display panel according to some embodiments of the present invention. As shown in FIGS. 1 to 4, in some embodiments, the panel inspection device 100 comprises an inspection plate 102, a carrier plate 104, a backlight module 106, a bracket assembly 108, and a first probe assembly 110. The inspection plate 102 has a first edge 112 and a second edge 114. The carrier plate 104 is disposed on the inspection plate 102, forming an opening 116 with the first edge 112 and the second edge 114. The backlight module 106 corresponds to the opening 116. The bracket assembly 108 comprises a first bracket 118, which is disposed on the first edge 112 and includes a first sliding groove 120. The first probe assembly 110 includes multiple first probes 122. The first probe assembly 110 is slidably disposed in the first sliding groove 120 and is movable between a first position and a second position. When the first probe assembly 110 is in the second position, the first probes 122 correspond to the inner side of the first edge 112.

The panel inspection device 100 is used for performing an inspection operation on a display panel 200. During the inspection operation, the panel inspection device 100 can transmit a control signal to the display panel 200 via the first probe assembly 110, causing the display panel 200 to generate a corresponding display mode (e.g., transparent, opaque, or partially transparent) according to the control signal.

As further shown in FIGS. 1 to 3, the inspection plate 102 has a first surface 101 and a second surface 103. The bracket assembly 108 and the first probe assembly 110 are disposed on the first surface 101. In some embodiments, the inspection plate 102 has a light-transmitting aperture 117. The first edge 112 may refer to the long side of the light-transmitting aperture 117, and the second edge 114 may refer to the short side of the light-transmitting aperture 117. However, this is not limiting; the first edge 112 could also be the short side, and the second edge 114 could be the long side. In some embodiments, the light-transmitting aperture 117 may be an open aperture (e.g., a U-shaped aperture) or a closed aperture. In the embodiment shown in FIG. 2, the light-transmitting aperture 117 is a closed aperture, with the first edge 112 being the long side of the light-transmitting aperture 117 and the second edge 114 being the short side.

As shown in FIG. 4, the carrier plate 104 is used to support the display panel 200. The carrier plate 104 may be fixed to the first surface 101 or embedded within the light-transmitting aperture 117. The phrase “the carrier plate 104 is disposed on the inspection plate 102 to form the opening 116 with the first edge 112 and the second edge 114” may refer to the scenario where the carrier plate 104 is fixed to the first surface 101, with the part of the light-transmitting aperture 117 not covered by the carrier plate 104 forming the opening 116. It may also refer to the scenario where the carrier plate 104 is embedded within the opening 116, with the portion of the light-transmitting aperture 117 that penetrates through the carrier plate 104 forming the opening 116. During the inspection operation, the display panel 200 can be supported on the opening 116, with the backlight module 106 corresponding to the position of the display panel 200.

In some embodiments, when the opening 116 is a closed aperture, the display panel 200 can rest on the inner side of the opening 116 (with the display panel 200 positioned between the first surface 101 and the second surface 103). In some embodiments, the size of the opening 116 can correspond to the maximum size of the display panel 200, allowing the opening 116 to support the largest or smaller size of display panel 200. During the inspection operation, the display panel 200 can abut both the first edge 112 and the second edge 114 on the same side, and the part of the opening 116 not covered by the display panel 200 can be shielded (as will be described later). In some embodiments, the area of the opening 116 is substantially equal to the area of the display panel 200. When the display panel 200 is supported on the opening 116, light leakage can be reduced or prevented. It should be noted that if display panels 200 with different sizes are to be inspected, the carrier plate 104 that matches the size of the display panel 200 can be replaced on the inspection plate 102.

The backlight module 106 is used to generate inspection light when driven. The backlight module 106 may be disposed on the second surface 103 of the inspection plate 102, such that the backlight module 106 corresponds to the opening 116 and emits inspection light towards the opening 116. In this way, the inspection light can serve as a backlight source for the display panel 200 to check whether the display state of the display panel 200 meets the inspection standards.

The bracket assembly 108 is disposed on the first surface 101 and can move the first probe assembly 110 so that the first probes 122 are electrically connected to at least one signal transmission portion 202 of the display panel 200. When the first bracket 118 is disposed on the first edge 112, the first sliding groove 120 extends along the X-axis direction in FIG. 3, allowing the first probe assembly 110 to move along the X-axis direction in the first sliding groove 120. If the signal transmission portions 202 of display panels 200 with different sizes are located at different positions along the X-axis, the first probe assembly 110 can be adjusted in the X-axis direction via the first sliding groove 120 so that the first probes 122 correspond to the signal transmission portions 202. In some embodiments, the first bracket 118 may extend from the outer side of the first edge 112 towards the inner side of the first edge 112, such that the signal transmission portion 202 corresponds to the position of the first sliding groove 120. In some embodiments, the first bracket 118 may also be disposed on the second edge 114, and multiple first brackets 118 may be disposed on both the first edge 112 and the second edge 114 (as will be described later).

The phrase “the first probes 122 correspond to the inner side of the first edge 112” may refer to the first probes 122 corresponding to the signal transmission portion 202 located on the inner side of the first edge 112. When the first probes 122 contact the signal transmission portion 202, the first probe assembly 110 can transmit control signals via the first probes 122 to the signal transmission portion 202. In some embodiments, the second position may refer to the position where the first probes 122 and the signal transmission portion 202 are aligned on a plumb line (as shown in FIG. 4). Conversely, the first position may refer to other positions of the first probes 122 in the first sliding groove 120.

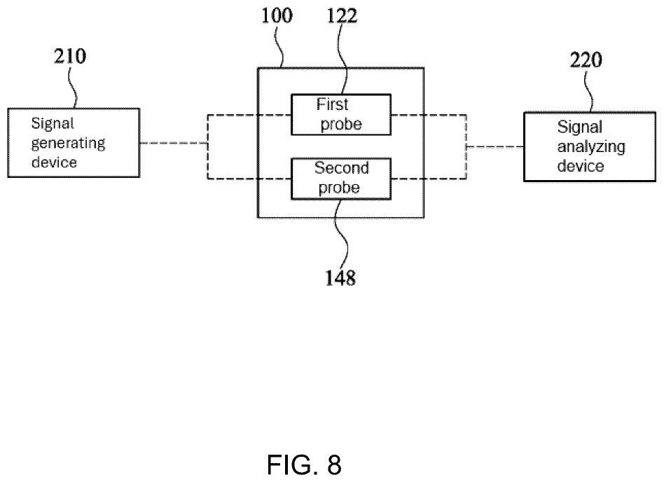

As further shown in FIGS. 1, 2, and 3, in some embodiments, the panel inspection device 100 further comprises a detection housing 124 and an actuating assembly 126. The detection housing 124 is connected to the inspection plate 102. The actuating assembly 126 connects the detection housing 124 and the bracket assembly 108. When actuated, the actuating assembly 126 positions the first probes 122 on the inner side of the first edge 112, allowing the first probes 122 to contact the signal transmission portion 202. It should be noted that before actuation, the first probes 122 are distant from the signal transmission portion 202. After actuation, the first probes 122 contact the signal transmission portion 202. In some embodiments, the signal generating device 210 and/or the signal analyzing device 220 may be housed in the detection housing 124 (as will be described in FIG. 8 later).

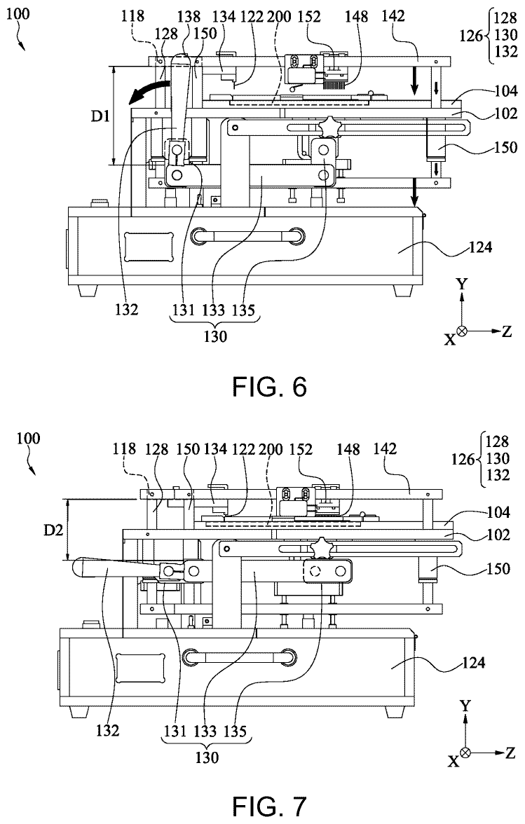

Reference to FIGS. 6 and 7. FIGS. 6 and 7 illustrate side views of the panel inspection device in some embodiments of the present invention. Specifically, FIG. 6 shows the position of the linkage assembly prior to actuation, while FIG. 7 depicts the position after actuation.

As shown in FIGS. 6 and 7, in some embodiments, the actuating assembly 126 includes a first elastic component 128, a linkage assembly 130, and an operating member 132. The first elastic component 128 is supported between the detection housing 124 and the first bracket 118. When actuated, it generates a telescopic movement.

The telescopic movement refers to the state where, prior to actuation, the first elastic component 128 has a first length (as shown in FIG. 6, the length of the first elastic component 128 along the Y-axis). After actuation, it has a second length (as shown in FIG. 7, the length of the first elastic component 128 along the Y-axis), wherein the first length is greater than the second length.

The linkage assembly 130 connects the detection housing 124 and the first bracket 118. The operating member 132 is connected to the linkage assembly 130 and, when actuated, the linkage assembly 130 actuates the first elastic component 128, causing the first elastic component 128 to shorten from the first length to the second length.

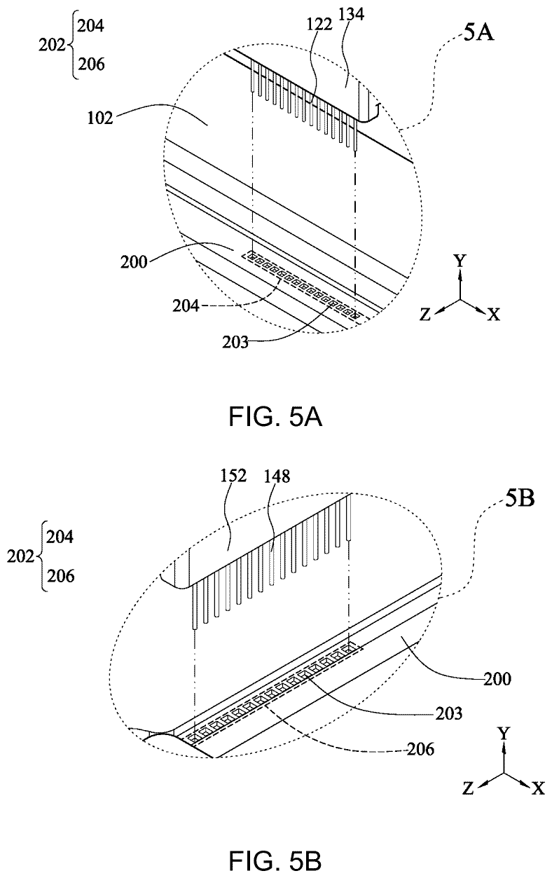

It should be noted that, when the first elastic component 128 is at the first length, the first probe 122 is positioned away from the signal transmission portion 202 (as further shown in FIGS. 5A and 5B). When the first elastic component 128 is at the second length, the first probe 122 makes contact with the signal transmission portion (202).

The first elastic component 128 may be implemented as a spring sleeve, a hydraulic rod, or a pneumatic rod.

Further reference to FIGS. 6 and 7. In some embodiments, as illustrated in FIGS. 6 and 7, the linkage assembly 130 may be implemented as a linkage group. For example, the linkage assembly 130 includes a first connecting rod 131, a second connecting rod 133, and a third connecting rod 135 sequentially connected. The first connecting rod 131 and the third connecting rod 135 are connected to the second surface 103 of the inspection plate 102.

When the operating member 132 is not actuated, the second connecting rod 133 maintains a first distance D1 from the first bracket 118, with the first elastic component 128 in its first length. Upon actuation of the operating member 132, the second connecting rod 133 transitions to a second distance D2 from the first bracket 118, compressing the first elastic component 128 to its second length. The first distance D1 is greater than the second distance D2.

In other words, the distance between the second connecting rod 133 and the first bracket 118 changes from the first distance D1 to the second distance D2, causing the first bracket 118 to move closer to the inspection plate 102. At the second distance D2, the first probe 122 makes contact with the signal transmission portion 202.

Further Reference to FIGS. 1, 2, and 3. In some embodiments, as shown in FIGS. 1, 2, and 3, the first probe assembly 110 further includes a first probe base 134. The first probe base 134 is equipped with a first adjustment sliding groove 136 and a first adjustment screw 138. The first adjustment screw 138 is positioned within both the first sliding groove 120 and the first adjustment sliding groove 136.

The first sliding groove 120 defines a first adjustment direction (e.g., along the X-axis in FIG. 3), while the first adjustment sliding groove 136 defines a second adjustment direction (e.g., along the Z-axis in FIG. 3). The first adjustment direction is perpendicular to the second adjustment direction.

Thus, the first probe base 134 can be moved between a first position and a second position along the first sliding groove 120 by adjusting the first adjustment screw 138, effectively changing the position of the first probe base 134 along the Y-axis in FIG. 3. Additionally, the first probe base 134 can be adjusted along the Z-axis in FIG. 3 by altering its position relative to the first adjustment screw 138 through the first adjustment sliding groove 136. This enables the first probe 122 to align with the signal transmission portion 202.

In some embodiments, the first probe assembly 110 further comprises a first connecting plate 140, where the first probes 122 are fixed to the first connecting plate 140, and the first connecting plate 140 is detachably assembled to the first probe base 134. It should be noted that the configuration of the signal transmission portion 202 of display panels 200 with different sizes may be the same or different. For example, for an 8-inch display panel 200, the contact width of the signal transmission portion 202 may be 1020 μm, and the contact distance may be 480 μm (as shown by the multiple contacts 203 of the signal transmission portion 202 in FIGS. 5A and 5B). Corresponding to the specifications of the signal transmission portion 202, the probe spacing of each first probe 122 on the first probe base 134 may be 1500 μm. Among 8-inch, 12.25-inch, and 12.3-inch display panels 200, the specifications of the signal transmission portion 202 are the same. Therefore, when inspecting 8-inch, 12.25-inch, or 12.3-inch display panels 200, the same specification of the first connecting plate 140 can be assembled to the first probe base 134 without replacing the first connecting plate 140. For example, for a 9-inch display panel 200, the contact width of the signal transmission portion 202 may be 460 μm, and the contact distance may be 330 μm. Corresponding to the specifications of the signal transmission portion 202, the probe spacing of each first probe 122 on the first probe base 134 may be 790 μm. Therefore, if the object to be inspected changes from an 8-inch display panel 200 to a 9-inch display panel 200, the corresponding specification of the first connecting plate 140 can be replaced on the first probe base 134 to match the contact specifications of the 9-inch display panel 200.

Please refer to FIGS. 4, 5A, and 5B. FIG. 5A is an enlarged view of area 5A in FIG. 4, showing the first probe corresponding to the first sub-transmission portion. FIG. 5B is an enlarged view of area 5B in FIG. 4, showing the second probe corresponding to the second sub-transmission portion. As shown in FIGS. 4, 5A, and 5B, in some embodiments, the signal transmission portion 202 comprises a first sub-transmission portion 204 and a second sub-transmission portion 206. The first sub-transmission portion 204 is adjacent to the first edge 112, and the second sub-transmission portion 206 is adjacent to the second edge 114. In some embodiments, the bracket assembly 108 further comprises a second bracket 142 and a second probe assembly 144. The second bracket 142 is disposed on the second edge 114 and includes a second sliding groove 146. The second probe assembly 144 comprises multiple second probes 148. The second probe assembly 144 is slidably disposed in the second sliding groove 146 and is movable between a third position and a fourth position. When the second probe assembly 144 is in the fourth position, the second probes 148 correspond to the inner side of the second edge 114. Thus, the first probe assembly 110 can correspond to the first sub-transmission portion 204, and the second probe assembly 144 can correspond to the second sub-transmission portion 206. During the inspection operation, the panel inspection device 100 can transmit control signals to the first sub-transmission portion 204 via the first probe assembly 110 and/or to the second sub-transmission portion 206 via the second probe assembly 144. In some embodiments, the first probe assembly 110 and the second probe assembly 144 can receive control signals separately.

As shown in FIG. 4, in some embodiments, the structure of the second bracket 142 and the second probe assembly 144 may be the same as that of the first bracket 118 and the first probe assembly 110. The description of the first bracket 118 and the first probe assembly 110 mentioned above can be referenced. The difference from the previous embodiments is that the second position may refer to the position where the first probe 122 and the first sub-transmission portion 204 are aligned on a plumb line, while the first position may refer to other positions of the first probe 122 in the first sliding groove 120. The fourth position may refer to the position where the second probe 148 and the second sub-transmission portion 206 are aligned on a plumb line, while the third position may refer to other positions of the second probe 148 in the second sliding groove 146.

In some embodiments, when the actuating assembly 126 is actuated, the first probe 122 is positioned on the inner side of the first edge 112, and the second probe 148 is positioned on the inner side of the second edge 114. It should be noted that the actuating assembly 126 can synchronously or asynchronously bring the first probe 122 into contact with the first sub-transmission portion 204 and the second probe 148 into contact with the second sub-transmission portion 206 (as will be explained later).

In some embodiments, the actuating assembly 126 further comprises a second elastic component 150. The second elastic component 150 is supported between the detection housing 124 and the second bracket 142. The linkage assembly 130 connects the detection housing 124, the first bracket 118, and the second bracket 142. The operating member 132 is connected to the linkage assembly 130. When the operating member 132 is actuated, the linkage assembly 130 actuates the first elastic component 128 and the second elastic component 150, shortening the first elastic component 128 and the second elastic component 150 to the second length. Thus, the first bracket 118 connected to the first elastic component 128 and the second bracket 142 connected to the second elastic component 150 can be simultaneously driven, causing the first probe 122 to contact the first sub-transmission portion 204 and the second probe 148 to contact the second sub-transmission portion 206. The structure of the second elastic component 150 can be the same as that of the first elastic component 128, and the description of the first elastic component 128 mentioned above can be referenced.

In some embodiments, the second probe assembly 144 further comprises a second probe base 152. The second probe base 152 has a second adjustment sliding groove 154 and a second adjustment screw 156. The second adjustment screw 156 is positioned in the second sliding groove 146 and the second adjustment sliding groove 154. The second sliding groove 146 has a third adjustment direction (as shown by the Z-axis in FIG. 3), and the second adjustment sliding groove 154 has a fourth adjustment direction (as shown by the X-axis in FIG. 3), with the third adjustment direction being perpendicular to the fourth adjustment direction. Thus, the second probe base 152 can be moved to the third position or the fourth position in the second sliding groove 146 by the second adjustment screw 156 (i.e., adjusting the position of the second probe base 152 on the Z-axis in FIG. 3). The second probe base 152 can also be moved relative to the second adjustment screw 156 in the second adjustment sliding groove 154 (i.e., adjusting the position of the second probe base 152 on the X-axis in FIG. 3), so that the second probe 148 corresponds to the second sub-transmission portion 206.

In some embodiments, the second probe assembly 144 further comprises a second connecting plate 158. The second probes 148 are fixed to the second connecting plate 158. The second connecting plate 158 is detachably assembled to the second probe base 152. It should be noted that the specifications (e.g., probe spacing) of the second probes 148 on the second connecting plate 158 may be the same as those of the first probes 122 on the first connecting plate 140. Alternatively, the first connecting plate 140 or the second connecting plate 158 may be selected according to the specifications of the first sub-transmission portion 204 or the second sub-transmission portion 206 of the display panel 200.

In some embodiments, when the area of the opening 116 is larger than the area of the display panel 200, an uncovered area may be formed between the opening 116 and the display panel 200. A light-shielding plate (not shown in the figure) can be provided in the uncovered area to block light leakage. As shown in FIGS. 3 and 4, in some embodiments, the panel inspection device 100 further comprises a movable baffle 160. The movable baffle 160 is slidably disposed on the inspection plate 102. When actuated, the movable baffle 160 is positioned on the inner side of the first edge 112. When the display panel 200 is supported on the carrier plate 104 and the movable baffle 160 is actuated, the movable baffle 160 can move from the outer side of the first edge 112 to the inner side of the first edge 112 to cover a portion of the display panel 200. The movable baffle 160 can act as a stop for the display panel 200, keeping the display panel 200 supported on the carrier plate 104. It can also block the uncovered area to prevent light leakage. The movable baffle 160 can be disposed on the first edge 112 or the second edge 114 (as shown in FIG. 3, where the movable baffle 160 is disposed on the first edge 112). Alternatively, multiple movable baffles 160 can be respectively disposed on both the first edge 112 and the second edge 114. In some embodiments, the panel inspection device 100 further comprises another movable baffle 162. The other movable baffle 162 is pivotally disposed on the inspection plate 102. When actuated, the other movable baffle 162 is positioned on the inner side of the first edge 112 and the inner side of the second edge 114 to cover a portion of the display panel 200.

Please refer to FIG. 8. FIG. 8 is a block diagram of the panel inspection device, the signal generating device, and the signal analyzing device according to some embodiments of the present invention. As shown in FIG. 8, the control signal can be sent to the panel inspection device 100 via a detection signal generating device 210. The first probe assembly 110 can be connected to the detection signal generating device 210 via a signal line to receive the control signal. In some embodiments, a signal analyzing device 220 is electrically connected to the display panel 200 to capture a feedback signal generated by the display panel 200 in response to the control signal and to obtain an inspection result based on the feedback signal. In some embodiments, the inspection operation includes an open test or a short test. For example, in an open test, if the measured feedback signal is greater than a standard value, the result is determined to be a pass. Conversely, if the measured feedback signal is less than the standard value, the result is determined to be a fail. Similarly, in a short test, if the measured feedback signal is greater than the standard value, the result is determined to be a fail. Conversely, if the measured feedback signal is less than the standard value, the result is determined to be a pass. The feedback signal can be, for example, one or a combination of working voltage (VDD), gate high voltage (VGH), gate low voltage (VGL), common voltage (VCOM), and source waveform signals.

In summary, according to some embodiments of the present invention, a panel inspection device 100 is provided, wherein during the inspection operation, the display panel 200 can be supported on the carrier plate 104. The first probe assembly 110, corresponding to the specifications of the display panel 200, is adjusted to the signal transmission portion 202 of the display panel 200 by sliding in the first sliding groove 120 of the first bracket 118. When the first probes 122 contact the signal transmission portion 202, the display mode of the display panel 200 can be controlled to perform the inspection operation. The carrier plate 104 can support display panels 200 with different sizes, and the inspection light generated by the backlight module 106 is suitable as a backlight source for display panels 200 with different sizes, illuminating the display panel 200 through the opening 116 to inspect the display state of the display panel 200. In some embodiments, when the signal transmission portion 202 of the display panel 200 is located at both the first edge 112 and the second edge 114, the first probe assembly 110 can be adjusted to correspond to the first sub-transmission portion 204 by sliding in the first sliding groove 120 of the first bracket 118. The second probe assembly 144 can be adjusted to correspond to the second sub-transmission portion 206 by sliding in the second sliding groove 146 of the second bracket 142. Thus, the panel inspection device 100 can measure and control the display panel 200 using both the first probe assembly 110 and the second probe assembly 144.

What is claimed is:

1. A panel inspection device, comprising:
an inspection plate having a first edge and a second edge;
a carrier plate disposed on the inspection plate, the carrier plate forming an opening with the first edge and the second edge;
a backlight module corresponding to the opening;
a bracket assembly comprising a first bracket, the first bracket being disposed on the first edge and having a first sliding groove; and
a first probe assembly comprising a plurality of first probes, the first probe assembly being slidably disposed in the first sliding groove and movable between a first position and a second position, wherein when the first probe assembly is in the second position, the first probes correspond to the inner side of the first edge.

2. The panel inspection device of claim 1, further comprising:
a detection housing connected to the inspection plate; and
an actuating assembly connecting the detection housing and the bracket assembly, wherein when actuated, the first probe is positioned on the inner side of the first edge.

3. The panel inspection device of claim 2, wherein the actuating assembly comprises:
a first elastic component supported between the detection housing and the first bracket, configured to generate telescopic movement upon actuation;
a linkage assembly connecting the detection housing and the first bracket; and
an operating member connected to the linkage assembly, wherein when actuated, the linkage assembly actuates the first elastic component.

4. The panel inspection device of claim 3, wherein the first probe assembly further comprises a first probe base having a first adjustment sliding groove and a first adjustment screw, the first adjustment screw being disposed within the first sliding groove and the first adjustment sliding groove, wherein the first sliding groove has a first adjustment direction, and the first adjustment sliding groove has a second adjustment direction, the first adjustment direction being perpendicular to the second adjustment direction.

5. The panel inspection device of claim 4, wherein the first probe assembly further comprises a first connecting plate, the first probes being fixed to the first connecting plate, the first connecting plate being detachably assembled to the first probe base.

6. The panel inspection device of claim 5, wherein the bracket assembly further comprises:
a second bracket disposed on the second edge and having a second sliding groove; and
a second probe assembly comprising a plurality of second probes, the second probe assembly being slidably disposed in the second sliding groove and movable between a third position and a fourth position, wherein when the second probe assembly is in the fourth position, the second probes correspond to the inner side of the second edge.

7. The panel inspection device of claim 6, wherein when the actuating assembly is actuated, the first probe is positioned on the inner side of the first edge and the second probe is positioned on the inner side of the second edge.

8. The panel inspection device of claim 6, wherein the actuating assembly further comprises:
a second elastic component supported between the detection housing and the second bracket, configured to generate the telescopic movement upon actuation;
the linkage assembly connecting the detection housing, the first bracket, and the second bracket; and
the operating member connected to the linkage assembly, wherein when actuated, the linkage assembly actuates both the first elastic component and the second elastic component.

9. The panel inspection device of claim 6, wherein the second probe assembly further comprises a second probe base having a second adjustment sliding groove and a second adjustment screw, the second adjustment screw being disposed within the second sliding groove and the second adjustment sliding groove, wherein the second sliding groove has a third adjustment direction, and the second adjustment sliding groove has a fourth adjustment direction, the third adjustment direction being perpendicular to the fourth adjustment direction.

10. The panel inspection device of claim 9, wherein the second probe assembly further comprises a second connecting plate, the second probes being fixed to the second connecting plate, the second connecting plate being detachably assembled to the second probe base.

11. The panel inspection device of claim 1, further comprising a movable baffle slidably disposed on the inspection plate, wherein when actuated, the movable baffle is positioned on the inner side of the first edge.
